(19) United States
(12) Patent Application Publication
(10) Pub. No.: US 2010/0323121 A1
(43) Pub. Date: Dec. 23, 2010

(54) Method of preparing a diaphragm of high purity polysilicon with multi-gas microwave source

(76) Inventors: Haibiao Wang, Shanghai (CN); Zhongdao Yan, Sapporo (JP); Fangtai Ma, Shanghai (CN); Cecilia Wang, Shanghai (CN)

Correspondence Address: ZHEN ZHENG LU, 1730 HUNTINGTON DRIVE #304, DUARTE, CA, 91010, US

(21) Appl. No.: 12/487,624

(22) Filed: Jun. 18, 2009

(51) Int. Cl. C23C 14/14

(52) U.S. Cl. 427/527

(57) ABSTRACT

A method of preparing a diaphragm of high purity polysilicon continuously, includes: impacting high purity silane gas molecules with a high temperature Argon ion beam source in a microwave resonator, so as to make an energy of the high purity silane gas molecules close to a particle binding energy of formation and form grains on a surface of the substrate when the high purity silane gas molecules reach a substrate of the microwave resonator, wherein the particle binding energy is more than 50 kev, the grains have diameters of about 50 nm.

### BACKGROUND OF THE PRESENT INVENTION

1. Field of Invention

The present invention relates to a method of preparing polysilicon diaphragm, and more particularly to a method of preparing diaphragm of high purity polysilicon with multi-gas microwave source.

2. Description of Related Arts

High purity polysilicon is an important material in producing solar cells and other electrical products. However, the conventional technology of producing polysilicon have several drawbacks.

The conventional technology generally obtains rod-like or granular polysilicon. Before using the rod-like or granular polysilicon to produce solar cells, it must be remelted or pulled crystal into thin section. As a result, it takes more cost and time to produce solar cells with the rod-like or granular polysilicon.

Therefore, to overcome the defects of shape, polysilicon diaphragm has become a better choice. However, during production, it is easy for the polysilicon diaphragm to have patches, cracks and crystal defects. The patches, cracks and crystal defects reduce the quality of product and cost waste.

### SUMMARY OF THE PRESENT INVENTION

An object of the present invention is to provide a method of preparing a diaphragm of high purity polysilicon continuously, which is capable of producing polysilicon diaphragm continuously, and reduces patches, cracks and crystal defects to a minimum level, so as to increase quality of product and have good economic effect.

Another object of the present invention is to provide a method of preparing a diaphragm of high purity polysilicon, which is applicable to low-cost mass manufacture of various kinds of photovoltaic polysilicon solar cells.

Another object of the present invention is to provide a method of preparing a diaphragm of high purity polysilicon, wherein the diaphragm of high purity polysilicon does not need remelting or crystal pulling as rod-like or granular polysilicon, and therefore can be provided directly to photovoltaic cell production.

Another object of the present invention is to provide a method of preparing a diaphragm of high purity polysilicon, which is applicable to preparing photovoltaic polycrystalline cell diaphragm, so that a manufacturing of solar cells is simplified greatly, and a product efficiency thereof is increased. Besides, the method is safe and green, saves raw materials and reduces energy consumption. Further, a product produced by the method has the advantages of high purity, crystal integrity, uniform resistivity, electrical properties stability, long life, less crystal defects, and is easier to control a thickness of film processing.

Accordingly, in order to accomplish the above objects, the present invention provides a method of preparing a diaphragm of high purity polysilicon continuously, comprising:

impacting high purity silane gas molecules with a high temperature Argon ion beam source in a microwave resonator, so as to make an energy of the high purity silane gas molecules close to a particle binding energy of formation and form grains on a surface of the substrate when the high purity silane gas molecules reach a substrate of the microwave resonator, wherein the particle binding energy is more than 50 kev, the grains have diameters of about 50 nm.

When the method is applied in preparing photovoltaic polycrystalline cell diaphragm, a manufacturing of solar cells is simplified greatly, and a product efficiency thereof is increased. Besides, the method is safe and green, saves raw materials and reduces energy consumption. Further, a product produced by the method has the advantages of high purity, crystal integrity, uniform resistivity, electrical properties stability, long life, less crystal defects, and is easier to control a thickness of film processing.

These and other objectives, features, and advantages of the present invention will become apparent from the following detailed description and the appended claims.

### DETAILED DESCRIPTION OF THE PREFERRED EMBODIMENT

A method of preparing a diaphragm of high purity polysilicon continuously according to a preferred embodiment of the present invention is illustrated, comprising:

impacting high purity silane gas molecules with a high temperature Argon ion beam source in a microwave resonator, so as to make an energy of the high purity silane gas molecules close to a particle binding energy of formation and form grains on a surface of the substrate when the high purity silane gas molecules reach a substrate of the microwave resonator, wherein the particle binding energy is more than 50 kev, the grains have diameters of about 50 nm.

A principle of the method is bombarding the high purity silane molecules with an inert gas ion source in a high temperature microwave quartz cavity. Particularly, when the ions enter into a microwave shielding working area, the silane molecules are split by transferred particle momentum, so as to make the separated pure silicon particles deposit on the surface of the substrate, which is made of glass and is preheated, to form a crystal epitaxial growth film or ceramic particles. It is worth mentioning that, a microwave field outside the working area is evenly annealed, so as to improve crystallization quality of the diaphragm, reduce cracks on crystal plane, and control pinholes and other defects.

The substrate is made by covering a pure silicon nitride membrane material on a surface of a conductive material comprising conductive glass and conductive ceramic, and the substrate is heated with microwave to maintain a certain working temperature thereof, so that high-energy beam of silane is concentrated on the surface of the substrate to decompose and deposit.

The present invention adopts a method of high-energy ion beam deposition to prepare nano-scale polycrystalline silicon films. Particularly, charge energy cluster and beam deposition makes hundreds or thousands of atoms arrive at the substrate at a same rate, and form an ordered polycrystalline body surface. Additionally, when nano-particles having a certain kinetic energy contact with the substrate, a binding energy between the nano-particles is conducive to uniform growth of nuclei of different orientation in dense accumulation structure.

Particularly, the substrate is non-oriented high-temperature materials, such as glass, ceramics and other absorbing materials. By heating the substrate with microwave to maintain a certain working temperature thereof, the high-energy beam of silane is concentrated on the surface of the substrate to decompose and deposit.

The substrate is made by covering a pure silicon nitride membrane material on a surface of conductive quartz glass or ceramic.

Specifically, impacting the high purity silane gas molecules with the high temperature Argon ion beam source comprises the steps of:

fixing a plurality of ceramic or glass substrates on a microwave quartz boat which is capable of rotating on a plane, warming the substrates gradually and uniformly with a microwave vacuum furnace device which has an energy below 45 kw, and then placing the substrates in a vacuum polysilicon deposition chamber, keeping a temperature thereof in 300˜800° C. for several minutes via the microwave working area;

at the same time, filling the vacuum polysilicon deposition chamber with 6N high purity silane gas and pure argon buffer gas of a certain pressure, wherein the pressure is usually lower than 1.5 atmospheric pressure, and a current capacity is 50 sccm; and

scanning the surface of the substrate back and forth rapidly with a source, which is preferably embodied as an excimer laser source or a high-temperature pure Argon ion source, on a top of the vacuum polysilicon deposition chamber, so as to heat and melt a part of crystal lattice thereof instantaneously to form an uniform polysilicon diaphragm.

Further, the polysilicon diaphragm is supported by a supporter which is controlled by an elevator at a base of a microwave crystallization room. The supporter is capable of rotating in the microwave crystallization room. When a crystallization cycle finishes (approximately 1-10 minutes), a following supporter enters a microwave preheating zone, and the supporter is withdrawn from the microwave crystallization zone and is returned back to an annealing zone to take materials again.

To prevent and avoid polysilicon patches, cracks and crystal defects of the polysilicon diaphragm, the method further comprises extending an annealing time and reducing a temperature gradient, so as to reduce stress and deformation between crystal lattices when amorphous molecules or microcrystalline molecules convert to a polycrystalline structure.

The method of preparing a diaphragm of high purity polysilicon according to the present invention is applicable to low-cost mass manufacture of various kinds of photovoltaic polysilicon solar cells. The diaphragm of high purity polysilicon does not need remelting or crystal pulling as rod-like or granular polysilicon, and therefore can be provided directly to photovoltaic cell production.

When the method is applied in preparing photovoltaic polycrystalline cell diaphragm, a manufacturing of solar cells is simplified greatly, and a product efficiency thereof is increased. Besides, the method is safe and green, saves raw materials and reduces energy consumption. Further, a product produced by the method has the advantages of high purity, crystal integrity, uniform resistivity, electrical properties stability, long life, less crystal defects, and is easier to control a thickness of film processing.

One skilled in the art will understand that the embodiment of the present invention as described above is exemplary only and not intended to be limiting.

It will thus be seen that the objects of the present invention have been fully and effectively accomplished. Its embodiments have been shown and described for the purposes of illustrating the functional and structural principles of the present invention and is subject to change without departure from such principles. Therefore, this invention includes all modifications encompassed within the spirit and scope of the following claims.

What is claimed is:

1. A method of preparing a diaphragm of high purity polysilicon, comprising:
impacting high purity silane gas molecules with a high temperature Argon ion beam source in a microwave resonator, so as to make an energy of the high purity silane gas molecules close to a particle binding energy of formation and form grains on a surface of the substrate when the high purity silane gas molecules reach a substrate of the microwave resonator, wherein the particle binding energy is more than 50 kev.

2. The method, as recited in claim 1, wherein impacting the high purity silane gas molecules with the high temperature Argon ion beam source comprises the steps of:
a) fixing a plurality of substrates on a microwave quartz boat which is capable of rotating on a plane, warming the substrates gradually and uniformly with a microwave vacuum furnace device which has an energy below 45 kw, then placing the substrates in a vacuum polysilicon deposition chamber, and keeping a temperature thereof in 300˜800° C. for several minutes via the microwave working area;
b) at the same time, filling the vacuum polysilicon deposition chamber with 6N high purity silane gas and pure argon buffer gas of a certain pressure, wherein the pressure is lower than 1.5 atmospheric pressure; and
c) scanning the surface of the substrate back and forth with a source on a top of the vacuum polysilicon deposition chamber, so as to heat and melt a part of crystal lattice thereof instantaneously to form an uniform polysilicon diaphragm.

3. The method, as recited in claim 1, wherein a microwave field outside a microwave shielding working area is evenly annealed, so as to improve crystallization quality of the diaphragm, reduce cracks on crystal plane, and control pinholes and other defects.

4. The method, as recited in claim 2, wherein a microwave field outside a microwave shielding working area is evenly annealed, so as to improve crystallization quality of the diaphragm, reduce cracks on crystal plane, and control pinholes and other defects.

5. The method, as recited in claim 1, wherein the substrate is a non-oriented high-temperature material, so that by heating the substrate with microwave to maintain a certain working temperature thereof, a high-energy beam of silane is concentrated on the surface of the substrate to decompose and deposit.

6. The method, as recited in claim 2, wherein the substrate is a non-oriented high-temperature material, so that by heating the substrate with microwave to maintain a certain working temperature thereof, a high-energy beam of silane is concentrated on the surface of the substrate to decompose and deposit.

7. The method, as recited in claim 4, wherein the substrate is a non-oriented high-temperature material, so that by heating the substrate with microwave to maintain a certain working temperature thereof, a high-energy beam of silane is concentrated on the surface of the substrate to decompose and deposit.

8. The method, as recited in claim 5, wherein the substrate is preferably made by covering a pure silicon nitride membrane material on a surface of a conductive material.

9. The method, as recited in claim 6, wherein the substrate is preferably made by covering a pure silicon nitride membrane material on a surface of a conductive material.

10. The method, as recited in claim 7, wherein the substrate is preferably made by covering a pure silicon nitride membrane material on a surface of a conductive material.

11. The method, as recited in claim 1, wherein the polysilicon diaphragm is supported by a supporter which is controlled by an elevator at a base of a microwave crystallization room, wherein the supporter is capable of rotating in the microwave crystallization room, when a crystallization cycle finishes, a following supporter enters a microwave preheating zone, and the supporter is withdrawn from the microwave crystallization zone and is returned back to an annealing zone to take materials again.

12. The method, as recited in claim 2, wherein the polysilicon diaphragm is supported by a supporter which is controlled by an elevator at a base of a microwave crystallization room, wherein the supporter is capable of rotating in the microwave crystallization room, when a crystallization cycle finishes, a following supporter enters a microwave preheating zone, and the supporter is withdrawn from the microwave crystallization zone and is returned back to an annealing zone to take materials again.

13. The method, as recited in claim 5, wherein the polysilicon diaphragm is supported by a supporter which is controlled by an elevator at a base of a microwave crystallization room, wherein the supporter is capable of rotating in the microwave crystallization room, when a crystallization cycle finishes, a following supporter enters a microwave preheating zone, and the supporter is withdrawn from the microwave crystallization zone and is returned back to an annealing zone to take materials again.

14. The method, as recited in claim 8, wherein the polysilicon diaphragm is supported by a supporter which is controlled by an elevator at a base of a microwave crystallization room, wherein the supporter is capable of rotating in the microwave crystallization room, when a crystallization cycle finishes, a following supporter enters a microwave preheating zone, and the supporter is withdrawn from the microwave crystallization zone and is returned back to an annealing zone to take materials again.

15. The method, as recited in claim 10, wherein the polysilicon diaphragm is supported by a supporter which is controlled by an elevator at a base of a microwave crystallization room, wherein the supporter is capable of rotating in the microwave crystallization room, when a crystallization cycle finishes, a following supporter enters a microwave preheating zone, and the supporter is withdrawn from the microwave crystallization zone and is returned back to an annealing zone to take materials again.

16. The method, as recited in claim 1, further comprising extending an annealing time and reducing a temperature gradient, so as to reduce stress and deformation between crystal lattices when amorphous molecules or microcrystalline molecules convert to a polycrystalline structure.

17. The method, as recited in claim 5, further comprising extending an annealing time and reducing a temperature gradient, so as to reduce stress and deformation between crystal lattices when amorphous molecules or microcrystalline molecules convert to a polycrystalline structure.

18. The method, as recited in claim 8, further comprising extending an annealing time and reducing a temperature gradient, so as to reduce stress and deformation between crystal lattices when amorphous molecules or microcrystalline molecules convert to a polycrystalline structure.

19. The method, as recited in claim 11, further comprising extending an annealing time and reducing a temperature gradient, so as to reduce stress and deformation between crystal lattices when amorphous molecules or microcrystalline molecules convert to a polycrystalline structure.

20. The method, as recited in claim 15, further comprising extending an annealing time and reducing a temperature gradient, so as to reduce stress and deformation between crystal lattices when amorphous molecules or microcrystalline molecules convert to a polycrystalline structure.
